(19) United States
(12) Patent Application Publication
(10) Pub. No.: US 2007/0018340 A1
(43) Pub. Date: Jan. 25, 2007

(54) Integrated circuit pad with separate probing and bonding areas

(76) Inventors: Young-Dae Kim, Seoul (KR); Jung-Su Ryu, Seongnam-Si (KR); Yeon-Keun Chung, Yongin-Si (KR)

Correspondence Address: LAW OFFICE OF MONICA H CHOI, P O BOX 3424, DUBLIN, OH, 430160204, US

(21) Appl. No.: 11/492,522

(22) Filed: Jul. 25, 2006

(30) Foreign Application Priority Data
Jul. 25, 2005 (KR) 2005-67287

(51) Int. Cl. H01L 23/48

(52) U.S. Cl. 257/786

(57) ABSTRACT

A semiconductor device includes an integrated circuit and a pad coupled to the integrated circuit. The pad has a probing area and a bonding area, and a material of the pad has multiple heights from the probing area to the bonding area. Such heights allow for easy recognition for probing at the probing area, and any damage at the probing area does not degrade quality of wire bonding in the bonding area.

### BACKGROUND OF THE INVENTION

This application claims priority to Korean Patent Application No. 2005-67287, filed on Jul. 25, 2005 in the Korean Intellectual Property Office, the disclosure of which is incorporated herein in its entirety by reference.

1. Field of the Invention

The present invention relates generally to integrated circuits, and more particularly, to forming a pad of the integrated circuit with multiple heights from a probing area to a bonding area for defining such areas of the pad.

2. Description of the Related Art

FIG. 1 shows a conventional semiconductor device 10 having a central area with an integrated circuit fabricated therein. In addition, the semiconductor device 10 includes a plurality of pads 12 formed along the edges of the semiconductor device 10. The pads 12 provide external connection to nodes of the integrated circuit 11.

For example, probe tips of a tester are connected to the pads 12 for testing the integrated circuit 11. In addition, gold wires or solder balls are connected to the pads 12 during assembly of a semiconductor package including the semiconductor device 10.

After fabrication of the semiconductor device 10, an electrical die sorting (EDS) process is performed for testing the functionality of the semiconductor device 10. A probe tip is placed onto the pad 12 of the semiconductor device 10 for transmitting a test signal between a tester and the integrated circuit 11. However, such a probe tip may damage the pad as the probe tip is placed down onto the pad several times.

FIG. 2 is a view of the semiconductor device 10 illustrating probing and bonding to the conventional pad 12. The white circular areas in FIG. 2 illustrate probing of the pad 12 during the EDS process. The shaded circular area in FIG. 2 illustrates bonding to the pad 12.

The pad 12 may be damaged from the pressure applied by the probe tip onto the pad 12, especially with probing of the pad 12 multiple times. The pad 12 is then attached on a lead frame through a bonding wire for forming a semiconductor package. However, the damage from the probing of the pad 12 may result in a low quality contact for the bonding wire to the pad 12. Such low quality contact is especially more likely in recent semiconductor devices having pads with fine pitch.

U.S. Pat. No. 5,506,499 to Puar discloses using separate pads for probing and bonding. However, such separate pads undesirably result in a larger semiconductor die. U.S. Pat. No. 6,563,226 to Harun et al. discloses depositing and patterning an additional material on top of the pad for defining separate areas for bonding and probing. However, depositing and patterning such additional material may contaminate the areas for bonding and probing the pad.

### SUMMARY OF THE INVENTION

Accordingly, embodiments of the present invention modify an existing material of a pad for defining a bonding area and a probing area of the pad.

A semiconductor device according to an aspect of the present invention includes an integrated circuit and a pad coupled to the integrated circuit. The pad has a probing area and a bonding area, and a material of the pad has multiple heights from the probing area to the bonding area.

In an embodiment of the present invention, the probing area of the pad has a first height, and the bonding area of the pad has a second height different from the first height. In an example embodiment of the present invention, a border between the probing and bonding areas is formed parallel to a scribe line of the semiconductor device.

In another embodiment of the present invention, a size of the probing area is substantially equal to a size of the bonding area.

In a further embodiment of the present invention, the pad is formed as an upper-most metal layer or as an intermediate metal layer below the upper-most metal layer.

In another embodiment of the present invention, the pad further includes a separation region disposed between the bonding area and the probing area. Such a separation region has a height that is different from each of the heights of the bonding and probing areas. In that case, the heights of the bonding and probing areas may be substantially equal. In an example embodiment of the present invention, the separation region is disposed parallel to a scribe line of the semiconductor device.

In a further embodiment of the present invention, the pad further includes a neighboring region surrounding the bonding and probing areas. Such a neighboring region has a height that is different from each of the heights of the bonding and probing areas. In that case, the heights of the bonding and probing areas may be substantially equal.

In another embodiment of the present invention, the pad further includes a horizontal region and a vertical region. The horizontal region is disposed between the bonding area and the probing area, and the horizontal region has a height that is different from each of the heights of the bonding and probing areas. The vertical region is disposed through each center of the bonding and probing areas, and the vertical region has a height that is different from each of the heights of the bonding and probing areas.

In this manner, the probing and bonding areas are defined as separate areas. Thus, probing of the pad is performed on the probing area, and wire bonding is connected onto the separate bonding area. Because the bonding area is not probed, the bonding area does not have damage from probing. Thus, the wire bonding quality is not degraded from probing during testing of the semiconductor device.

### BRIEF DESCRIPTION OF THE DRAWINGS

The above and other features and advantages of the present invention will become more apparent when described in detailed exemplary embodiments thereof with reference to the attached drawings in which:

FIG. 1 is a top view of a conventional semiconductor device;

FIG. 2 is an enlarged view of a conventional pad in the semiconductor device of FIG. 1;

FIG. 3 shows a pad having separate bonding and probing areas for a semiconductor device, according to an embodiment of the present invention;

FIG. 4 is a cross-sectional view of a pad formed with an upper-most metal layer, according to an embodiment of the present invention;

FIG. 5 is a top view of a semiconductor substrate having the semiconductor device of FIG. 3, according to an embodiment of the present invention;

FIG. 6 shows a pad having a separation region, according to another embodiment of the present invention;

FIG. 7 shows a pad having horizontal and vertical regions, according to another embodiment of the present invention;

FIG. 8 shows a pad having a neighboring region, according to another embodiment of the present invention;

FIG. 9 is a cross-sectional view of a pad formed with an intermediate metal layer, according to another embodiment of the present invention; and

FIG. 10 shows a top view of a semiconductor device having the pad of FIG. 3, according to an embodiment of the present invention.

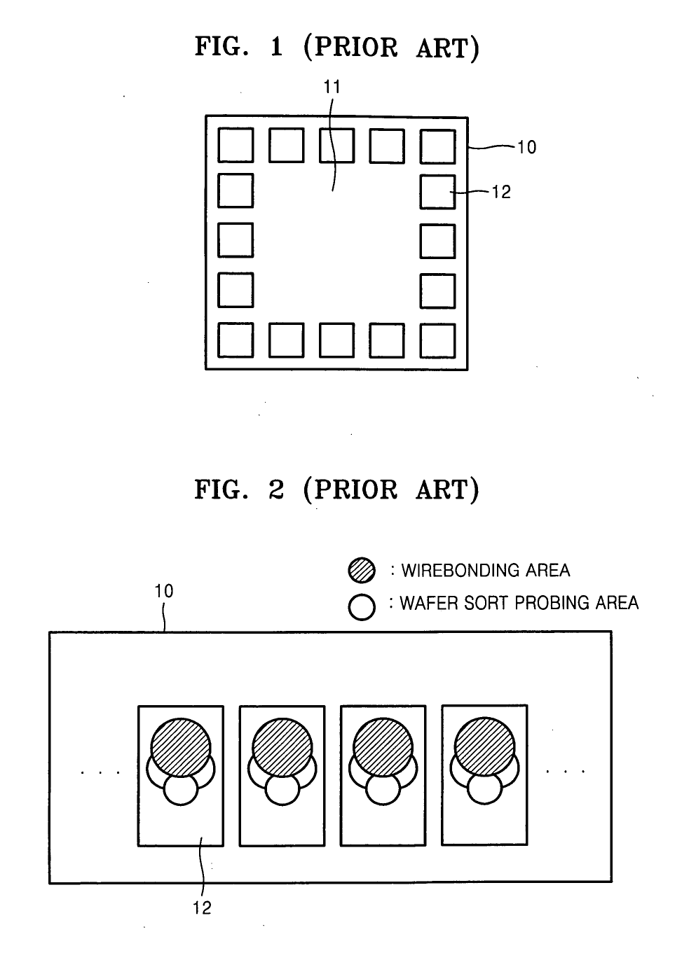

The figures referred to herein are drawn for clarity of illustration and are not necessarily drawn to scale. Elements having the same reference number in FIGS. 1, 2, 3, 4, 5, 6, 7, 8, 9, and 10 refer to elements having similar structure and/or function.

### DETAILED DESCRIPTION OF THE INVENTION

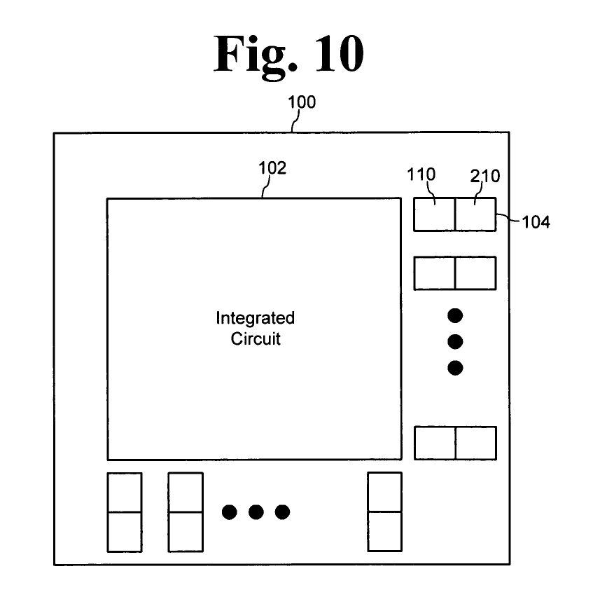

FIG. 10 shows a semiconductor device 100 having an integrated circuit 102 and a pad 104 fabricated thereon. The integrated circuit 102 is fabricated in a center region of a semiconductor substrate for the semiconductor device 100. A plurality of pads including an example pad 104 is formed toward the outer edges of the semiconductor device 100. The semiconductor device 100 may be one semiconductor die of the semiconductor substrate having multiple semiconductor dies fabricated thereon. The pad 104 is coupled to the integrated circuit 102 and provides external connection to a node of the integrated circuit 102.

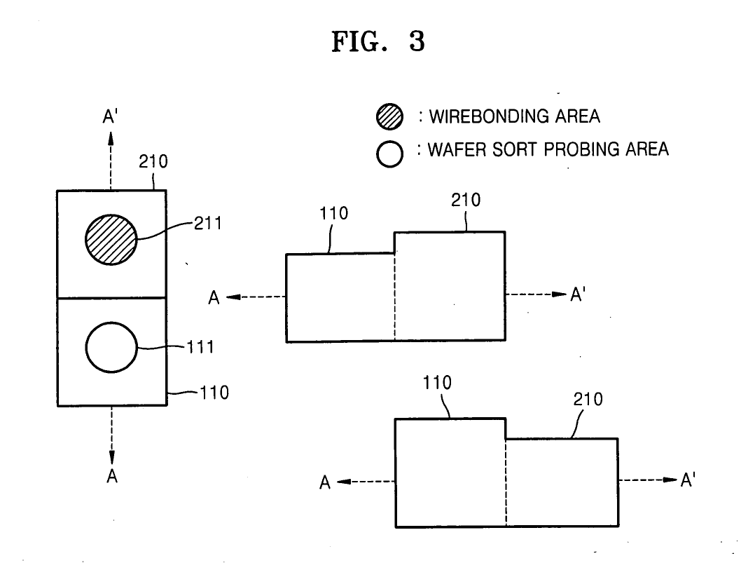

Referring to FIGS. 3 and 10, the example pad 104 is formed into a probing area 110 and a bonding area 210. The probing area 110 is for the area onto which a probe tip of a tester is connected during testing of the integrated circuit 102 such as for an EDS (electrical die sorting) process. A circular area 111 within the probing area 110 represents an area to which the probe tip is connected.

The bonding area 210 is for the area onto which a bonding wire is connected for coupling to a pin attached to a lead frame during packaging of the semiconductor device 100. A circular area 211 within the bonding area 210 represents an area to which the bonding wire is connected during manufacture of such packaging.

By having such separate areas 110 and 210 for probing and bonding, any pad damage from probing during testing is limited to the probing area 110. Thus, the quality of wire bonding onto the bonding area 210 is not compromised from such pad damage.

For defining such probing and bonding areas 110 and 210, a material of the pad 104 is formed with multiple heights from the probing area 110 to the bonding area 210. FIG. 3 also shows example cross-sectional views of the pad 104 along line A-A′. A height of the probing area 110 is different from a height of the bonding area 210.

FIG. 3 illustrates both cases of the height of the probing area 110 being less than and greater than the height of the bonding area 210. The probing area 110 and the bonding area 210 having different heights are more easily recognized as separate areas by an auto sensing mechanism in an EDS (electrical die sorting) system.

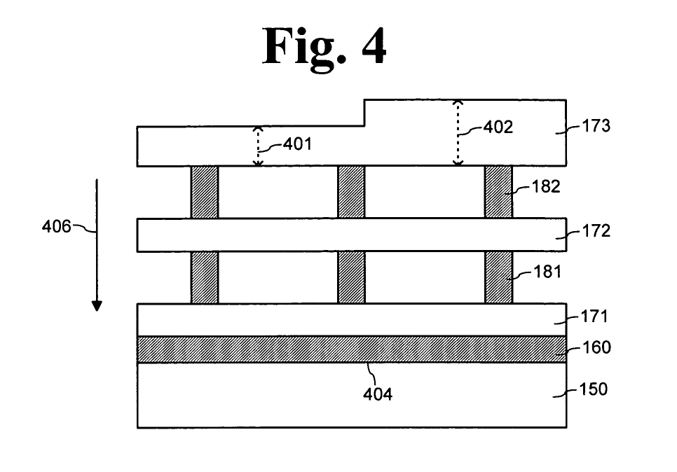

Referring to FIG. 4, such heights of the pad 104 are along a direction 406 that is perpendicular to a surface 404 of a semiconductor substrate 150 having the semiconductor device 100 fabricated thereon. FIG.4 is a cross-sectional view of the pad 100 formed as an upper-most metal layer 173.

Referring to FIGS. 3, 4, and 10, the integrated circuit 102 is formed with the semiconductor substrate 150. Thereafter, an inter-layer insulation layer 160 comprised of an oxidation layer or a nitride layer for example is formed onto the semiconductor substrate 150. A first metal layer 171 is then formed on the inter-layer insulation layer 160.

After an insulation layer (not shown) is formed and patterned on the first metal layer 171, via holes 181 are formed in such a patterned insulation layer. Also, a second metal layer 172 is formed with the via holes 181 becoming filled with a material of such a metal layer 172 to form vias 181. The first metal layer 171 is coupled to the second metal layer 172 with vias 181.

After another insulation layer (not shown) is formed and patterned on the second metal layer 172, via holes 182 are formed in such a patterned area. Furthermore, a third metal layer 173 is formed with the via holes 182 becoming filled with a material of such a metal layer 173 to form vias 182. The third metal layer 173 is an upper-most metal layer and is patterned and etched to form the height difference of the pad 104.

FIG. 4 illustrates a first portion of a material of the metal layer 173 having a first height 401 to form the probing area 110 of the pad 104. FIG. 4 also illustrates a second portion of the material of the metal layer 173 having a second height 402 to form the bonding area 210 of the pad 104.

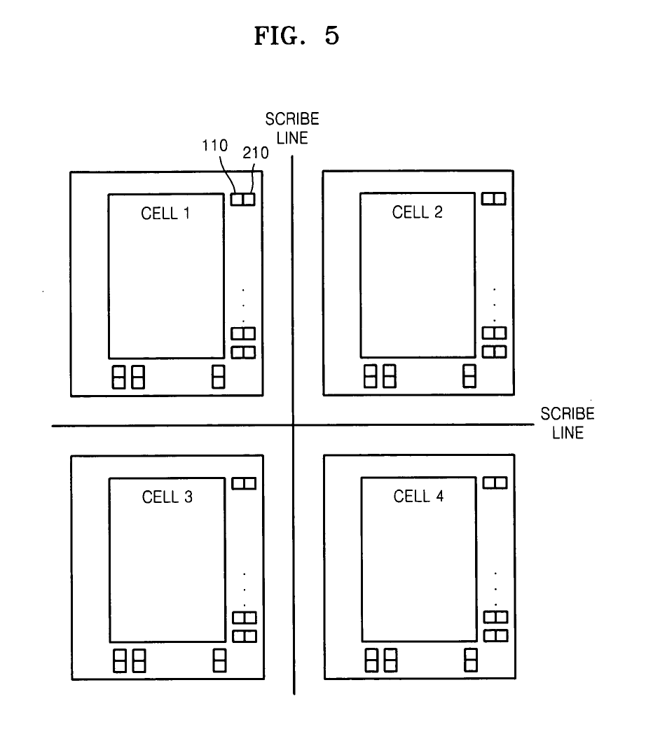

FIG. 5 shows an expanded top view of the semiconductor substrate 150 having the semiconductor device 100 fabricated thereon. Referring to FIGS. 5 and 10, the integrated circuit 102 is formed within a CELL 1. Each of CELL 1, CELL 2, CELL 3, and CELL 4 is for forming a respective semiconductor die, and such semiconductor die is separated by scribe lines.

In one embodiment of the present invention, a boundary between the probing area 110 and the bonding area 210 is parallel with an adjacent scribe line, as illustrated in FIG. 5. Further referring to FIG. 3, such a boundary is formed through a center of the pad 104 such that the size of the probing area 110 is substantially equal to the size of the bonding area 210.

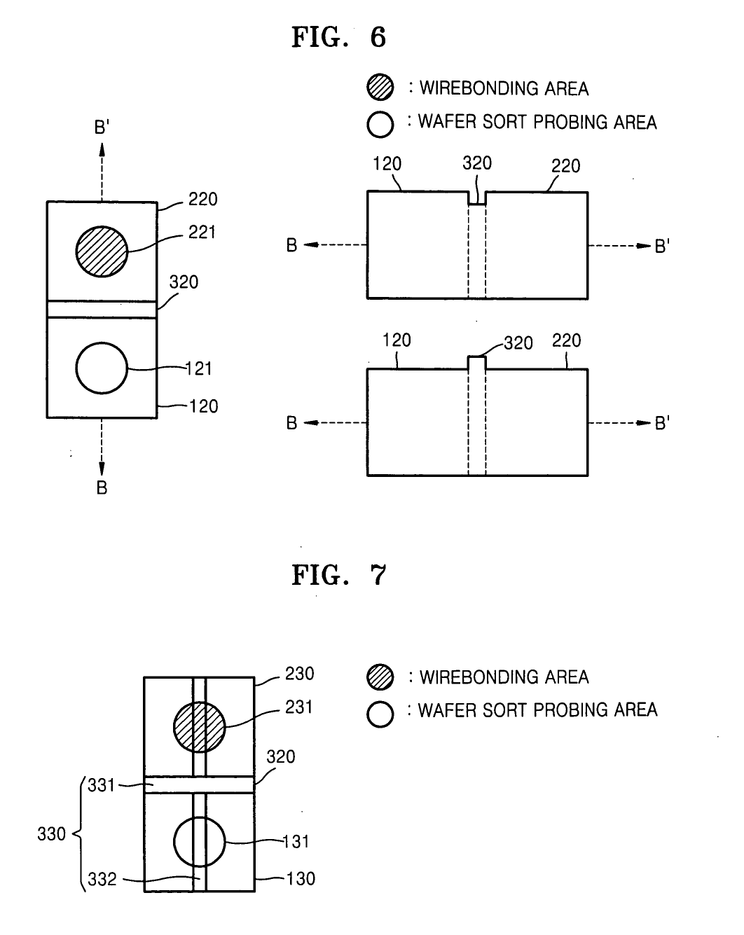

FIG. 6 shows a pad of a semiconductor device according to another embodiment of the present invention. Referring to FIG. 6, the material of the pad is formed to have a probing area 120 and a bonding area 220. In addition, the material of the pad is also formed to have a separation region 320 disposed between the probing area 120 and the bonding area 220.

FIG. 6 also shows a cross-sectional view of the pad across line B-B′ to illustrate that the height of the separation region 320 is different from each of the heights of the probing area 120 and the bonding area 220. The circular area 121 represents an area to which a probe tip is connected for the EDS testing process, and the circular area 221 represents an area to which a wire is bonded during semiconductor packaging.

In one embodiment of the present invention, the heights of the probing and bonding areas 120 and 220 are substantially same. However, the height of the separation region 320 is less than or greater than each of the heights of the probing and bonding areas 120 and 220 as illustrated in FIG. 6. With such a separation region 320, the probing area 120 is easily recognized from the bonding area 220 by an auto sensing mechanism in an EDS (electrical die sorting) system.

In one embodiment of the present invention, the separation region 320 is formed to be parallel to an adjacent scribe line, similarly as illustrated for the boundary between the probing and bonding areas in FIG. 5. In another embodiment of the present invention, the separation region 320 is formed through a center of the pad such that the size of the probing area 120 is substantially equal to the size of the bonding area 220.

FIG. 7 shows a pad of a semiconductor device according to another embodiment of the present invention. Referring to FIG. 7, the pad includes a probing area 130 and a bonding area 230. The circular area 131 represents an area to which a probe tip is connected for the EDS testing process, and the circular area 231 represents an area to which a wire is bonded during semiconductor packaging.

In addition, the material of the pad is formed with a horizontal region 331 disposed between the probing and bonding areas 130 and 230. Furthermore, the material of the pad is formed with a vertical region 332 extending through centers of the probing and bonding areas 130 and 230 and perpendicular to the horizontal region 331.

In one embodiment of the present invention, the heights of the probing and bonding areas 130 and 230 are substantially same. However, similar to the embodiment of FIG. 6, the horizontal region 331 of FIG. 7 has a height that is less than or greater than each of the heights of the probing and bonding areas 130 and 230. Thus, the probing area 130 is easily recognized from the bonding area 230 by an auto sensing mechanism in an EDS (electrical die sorting) system.

In addition, the vertical region 332 also has height that is less than or greater than each of the heights of the probing and bonding areas 130 and 230. Such height difference allows easy recognition of a center of the probing and bonding areas 130 and 230 for aiding in placement of a probe tip to a center of the probing area 130 and of a wire to a center of the bonding area 230. Thus, the point of intersection of the horizontal and vertical regions 330 is disposed at a center of the pad. Furthermore, the horizontal region 331 may be formed to be parallel to an adjacent scribe line.

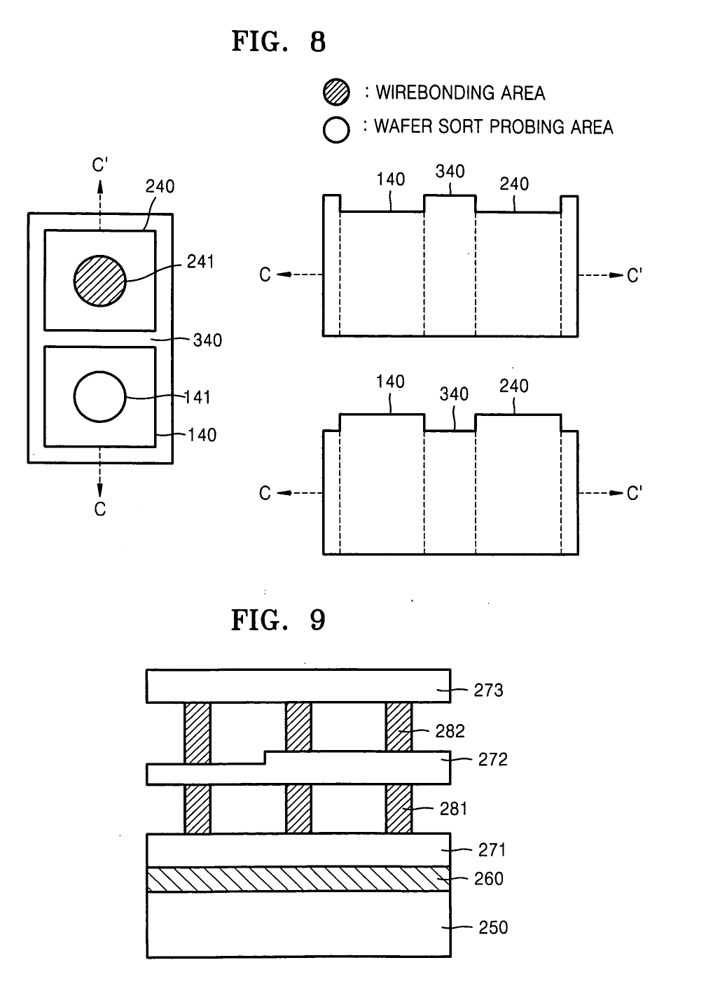

FIG. 8 shows a pad of a semiconductor device according to another embodiment of the present invention. Referring to FIG. 8, the pad includes a probing area 140 and a bonding area 240. The circular area 141 represents an area to which a probe tip is connected for the EDS testing process, and the circular area 241 represents an area to which a wire is bonded during semiconductor packaging.

In one embodiment of the present invention, the heights of the probing and bonding areas 140 and 240 are substantially same. However, the material of the pad is formed with a neighboring region 340 that surrounds the probing and bonding areas 140 and 240. FIG. 8 also shows cross-sectional views of the pad across line C-C′ for illustrating that the height of the neighboring region 340 is less than or greater than each of the heights of the probing and bonding areas 140 and 240. With such a height difference, the probing area 140 is easily recognized from the bonding area 240 by an auto sensing mechanism in an EDS (electrical die sorting) system.

FIG. 9 is a cross-sectional view of a pad formed as an intermediate metal layer 272 below an upper-most metal layer 273, according to another embodiment of the present invention. Referring to FIGS. 3, 9, and 10, the integrated circuit 102 is formed onto a semiconductor substrate 250. Thereafter, an inter-layer insulation layer 260 comprised of an oxidation layer or a nitride layer for example is formed onto the semiconductor substrate 250. A first metal layer 271 is then formed on the inter-layer insulation layer 260.

After an insulation layer (not shown) is formed and patterned on the first metal layer 271, via holes 281 are formed in such a patterned insulation layer. Also, a second metal layer 272 (i.e., the intermediate metal layer) is formed with the via holes 281 becoming filled with a material of such a metal layer 272 to form vias 281. The first metal layer 271 is coupled to the second metal layer 272 with vias 181.

The intermediate metal layer 272 may be patterned and etched to form a first portion having a lower height from a second portion for forming the pad 104 of FIG. 10. After another insulation layer (not shown) is formed and patterned on the second metal layer 272, via holes 282 are formed in such a patterned area. Furthermore, a third metal layer 273 is formed with the via holes 282 becoming filled with a material of such a metal layer 273 to form vias 282.

In this manner, the material of an integrated circuit pad is patterned and etched to form multiple heights from a probing area to a bonding area of the pad. Such different heights allow for easy recognition for probing at the probing area during testing of the integrated circuit. Any damage at the probing area does not degrade quality of wire bonding in the bonding area.

The foregoing is by way of example only and is not intended to be limiting. For example, any numbers or number of elements described and illustrated herein is by way of example only. The present invention is limited only as defined in the following claims and equivalents thereof.

What is claimed is:

1. A semiconductor device comprising:
an integrated circuit; and
a pad coupled to the integrated circuit, wherein the pad has a probing area and a bonding area, and wherein a material of the pad has multiple heights from the probing area to the bonding area.

2. The semiconductor device of claim 1, wherein the probing area of the pad has a first height, and wherein the bonding area of the pad has a second height different from the first height.

3. The semiconductor device of claim 1, wherein a border between the probing and bonding areas is parallel to a scribe line of the semiconductor device.

4. The semiconductor device of claim 1, wherein a size of the probing area is substantially equal to a size of the bonding area.

5. The semiconductor device of claim 1, wherein the pad is formed as an upper-most metal layer or as an intermediate metal layer below the upper-most metal layer.

6. The semiconductor device of claim 1, wherein the pad further includes:
a separation region disposed between the bonding area and the probing area, wherein the separation region has a height that is different from each of the heights of the bonding and probing areas.

7. The semiconductor device of claim 6, wherein the heights of the bonding and probing areas are substantially equal.

8. The semiconductor device of claim 6, wherein the separation region is disposed parallel to a scribe line of the semiconductor device.

9. The semiconductor device of claim 1, wherein the pad further includes:
a neighboring region surrounding the bonding and probing areas, wherein the neighboring region has a height that is different from each of the heights of the bonding and probing areas.

10. The semiconductor device of claim 9, wherein the heights of the bonding and probing areas are substantially equal.

11. The semiconductor device of claim 1, wherein the pad further includes:
a horizontal region disposed between the bonding area and the probing area, wherein the horizontal region has a height that is different from each of the heights of the bonding and probing areas; and
a vertical region disposed through each center of the bonding and probing areas, wherein the vertical region has a height that is different from each of the heights of the bonding and probing areas.

12. A method of forming a pad of a semiconductor device, comprising:
forming an integrated circuit in a semiconductor substrate;
forming a pad over the integrated circuit to have a probing area and a bonding area; and
forming a material of the pad to have multiple heights from the probing area to the bonding area.

13. The method of claim 12, further comprising:
forming the probing area of the pad to have a first height; and
forming the bonding area of the pad to have a second height different from the first height.

14. The method of claim 12, further comprising:
forming a border between the probing and bonding areas to be parallel to a scribe line of the semiconductor device.

15. The method of claim 12, wherein a size of the probing area is substantially equal to a size of the bonding area.

16. The method of claim 12, further comprising:
forming the pad as an upper-most metal layer or as an intermediate metal layer below the upper-most metal layer.

17. The method of claim 12, further comprising:
forming a separation region disposed between the bonding area and the probing area, wherein the separation region has a height that is different from each of the heights of the bonding and probing areas.

18. The method of claim 17, wherein the heights of the bonding and probing areas are substantially equal.

19. The method of claim 12, further comprising:
forming a neighboring region surrounding the bonding and probing areas, wherein the neighboring region has a height that is different from each of the heights of the bonding and probing areas.

20. The method of claim 19, wherein the heights of the bonding and probing areas are substantially equal.
